(19) United States
(12) Patent Application Publication
(10) Pub. No.: US 2024/0336824 A1
(43) Pub. Date: Oct. 10, 2024

(54) COOLANT COMPOSITION, EQUIPMENT CONTAINING SAME, AND METHOD OF COOLING EQUIPMENT USING SAME

(71) Applicants: SK INNOVATION CO., LTD., Seoul (KR); SK ENMOVE CO., LTD., Seoul (KR)

(72) Inventors: Kang Min JUNG, Daejeon (KR); Min Je PARK, Daejeon (KR); Hak Mook KIM, Daejeon (KR); Do Woan KIM, Daejeon (KR)

(21) Appl. No.: 18/434,813

(22) Filed: Feb. 7, 2024

(30) Foreign Application Priority Data
Apr. 4, 2023 (KR) 10-2023-0044338

(51) Int. Cl. C09K 5/10; H05K 7/20

(52) U.S. Cl. CPC C09K 5/10; H05K 7/20236

(57) ABSTRACT

The present invention disclosure provides a coolant composition, equipment containing the same coolant, and a method of cooling equipment using the same coolant. The coolant composition having a C value in a range of 3.000×10⁻² to 4.950×10⁻². The coolant composition is used for removing heat generated by equipment and the equipment is directly cooled by the coolant composition and the method comprises providing the coolant composition in direct contact with the equipment.

### CROSS REFERENCE TO RELATED APPLICATION

The present application claims priority to Korean Patent Application No. 10-2023-0044338, filed Apr. 4, 2023, the entire content of which is incorporated herein for all purposes by this reference.

### BACKGROUND OF THE DISCLOSURE

### 1. Field of the Disclosure

The present invention disclosure relates to a coolant composition, equipment containing the same, and a method of cooling the equipment using the same.

### 2. Description of the Related Art

A coolant plays a role in absorbing heat generated from a source of heat generation and reducing a temperature of the source of heat generation. Substances with the following characteristics are desirable as a coolant: a high thermal efficiency, a low viscosity, an affordable price, no toxicity, a chemical stability, and anti-corrosion in equipment.

With the high sophistication of a variety of electronic products such as electric vehicles, more heat is generated in use of the electronic products. Thus, controlling heat generated from electronic products is a necessary consideration to conveniently use products and prevent lifespan reduction of products.

Various conventional arts are present to cool down electronic products. Representative cooling methods are air cooling, water cooling, and oil cooling. It is advantageous that air cooling out of the methods does not require a separate cooling medium to be ready. However, the disadvantage of air cooling is a low cooling efficiency. Water cooling excels at cooling products due to a high thermal conductivity of water. However, the method is difficult to cool products through a direct contact with a source of heat generation.

### SUMMARY OF THE DISCLOSURE

The present invention disclosure provides a coolant composition, equipment containing the same, and a cooling method of cooling the equipment using the same, the coolant composition being excellent in insulation and cooling.

The first aspect of the present invention disclosure is a coolant composition in which C value of the following formula falls in a range of from 3.000×10⁻² to 4.950×10⁻². Herein, the formula is defined as follows:

$$C = 0.17 \times \frac{{ρ}^{0.428} \times {C}_{p}^{0.397} \times {k}^{0.51}}{{μ}^{0.245}}$$

Herein, ρ represents density (g/cm³), Cₚ represents specific heat (J/g° C.), k represents heat conductivity (W/mK), and μ represents kinematic viscosity (cSt) of the coolant composition.

In one embodiment, the coolant composition comprises mineral base oil in an amount of at least 90% by weight with respect to the total weight of the coolant composition.

In one embodiment, the mineral base oil is characterized by at least one of the following parameters: an average carbon number measured based on ASTM D2887 of 15 to 35 carbon atoms; a 5% by weight distillation temperature measured based on ASTM D2887 in a range of 240° C. to 410° C.; a 95% by weight distillation temperature measured based on ASTM D2887 in a range of 330° C. to 570° C.; and a paraffin volume measured based on ASTM D2786 of 90% or less based on the total volume of the mineral base oil.

In one embodiment, the mineral base oil is characterized by at least two of the parameters listed above.

In one embodiment, the mineral base oil is characterized by at least three of the parameters listed above.

In one embodiment, the mineral base oil is characterized by all four of the parameters listed above.

In one embodiment, the coolant composition further comprises additives.

In one embodiment, the additives comprise an antioxidant and other additives.

In one embodiment, the other additives may comprise an anti-foamer, a corrosion inhibitor, a detergent, a dispersing agent, a friction modifier, an anti-wear agent, an extreme-pressure additive, a viscosity index improver, a pour point depressant, a viscosity modifier, or any mixture thereof.

In one embodiment, the coolant composition has an electro-conductivity from 0 pS/m or more to 20 pS/m (picosiemens per meter) or less as measured by IEC 60247.

The second aspect of the present invention disclosure is equipment comprising the coolant composition according to the first aspect in which the coolant composition is used for removing heat generated by the equipment, and the equipment is directly cooled by the coolant composition.

The third aspect of the present invention disclosure is a method of cooling equipment, the method comprising a step of providing the coolant composition according to the first aspect in direct contact with the equipment, wherein the equipment in operation generates heat which is directly removed via the coolant composition.

The present invention disclosure provides a coolant composition excellent in insulation and cooling. The use of the coolant composition can provide an effective control over heat generated in equipment operation.

### BRIEF DESCRIPTION OF THE DRAWINGS

FIG. 1 is a schematic view illustrating cooling performance test according to the embodiments of the present invention disclosure.

### DESCRIPTION OF THE EMBODIMENTS

The objective, advantages, and characteristics of the present invention disclosure are further clarified in the following detailed description and various embodiments with reference to the accompanying FIGURE, but the present invention disclosure is not limited only to thereto. In addition, when it comes to the description of the present invention disclosure, when the detailed description on the notified technology is determined to obscure the gist of the present invention disclosure, the detailed description is omitted.

According to a first aspect of the present invention disclosure, a coolant composition is provided, the coolant composition including a base oil. In one embodiment, the base oil may be mineral oil. In another embodiment, the base oil may include mineral oil as a major base oil and Poly Alpha Olefins (PAOs), ester base oil, or both as a minor base oil. In the present invention disclosure, the major base oil may refer to a base oil whose weight percent with respect to the total base oil weight is more than 50% by weight.

In the present invention disclosure, the term “mineral oil” refers to oil obtained through crude oil refining from a crude oil refinery. PAOs are a type of synthetic hydrocarbon that are commonly used as base oils on various lubricants. Generally, PAOs exhibit a more excellent performance especially in high temperatures but are significantly more difficult to produce and, therefore, involve higher production cost than mineral oil. Although the composition of the present invention disclosure uses mineral oil as a major base oil, it is expected that at least equivalent performance and relatively affordable price may be simultaneously achieved compared with the case of using only the PAO. Meanwhile, the ester base oil exhibits an excellent heat conductivity but has polarity so that the ester base oil has a less insulation ability compared with mineral oil, and due to the possibility of hydrolysis, the ester base oil is weak at moisture. Therefore, the ester base oil is not suitable to be used as the major base oil of the present coolant composition.

In one embodiment of the present invention disclosure, the weight percent of the base oil may be at least 90% by weight with respect to the total weight of the coolant composition. Particularly, the weight percent of the base oil may be in a range of 90% by weight to 98% by weight such as 91% by weight to 95% by weight, 92% by weight to 97% by weight, 93% by weight to 96% by weight, or 94% by weight to 97.5% by weight. The weight percent of the base oil may be more particularly in a range of 92% by weight to 98% by weight and even more particularly in a range of 93% by weight to 98% by weight. When the weight percent of base oil is less than lower limits of the above ranges, more additives are required for producing a coolant composition. This result in an increase in the price of the coolant composition due to the high cost of the additives, which is undesirable. The balance of the coolant composition may include one or more additives.

In the present invention disclosure, a coolant composition may include any mineral base oil as long as the coolant composition has a C value falling within the predetermined ranges described below or has the predetermined electro-conductivity described below. For example, the mineral base oil of the present invention disclosure may include at least one of the following characteristics. In an embodiment, the mineral base oil may include two of the following characteristics. In another embodiment, the mineral base oil may include three of the following characteristics. In yet another embodiment, the mineral base oil may include all of the following characteristics:
In terms of the average carbon number measured based on ASTM D2887, the mineral base oil may have 15 to 35 carbon atoms on average;
In terms of a 5% by weight distillation temperature measured based on ASTM D2887, the mineral base oil may have a 5% by weight distillation temperature in a range of 240° C. to 410° C.;
In terms of a 95% by weight distillation temperature measured based on ASTM D2887, the mineral base oil may have a 95% by weight distillation temperature in a range of 330° C. to 570° C.;
In terms of the paraffin volume measured based on ASTM D2786, the mineral base oil may have paraffin in an amount of 90% by volume or less based on the total volume of the mineral base oil.

In the case where at least one parameter range is below the numerical range described above (average carbon number, 5% by weight distillation temperature, and 95% by weight distillation temperature of the mineral base oil included in the coolant composition), the amount of volatile oil fraction in the composition increases so that poor stability may occur. Conversely, in the case where at least one parameter range is above the numerical ranges described above, the kinematic viscosity of the coolant composition increases, which leads to a poor flow characteristic which in return results in decreased cooling efficiency.

The coolant composition of the present invention disclosure may further include one or more additives. Suitable additives may include antioxidants, other additives, or both. Herein, the other additives refer to additives capable of being added to the composition of the present invention disclosure other than an antioxidant. The other additives are not particularly limited unless the additives interfere with the objective of the present invention disclosure. Examples of other additives may comprise antifoamers, corrosion inhibitors, detergents, dispersing agents, friction modifiers, anti-wear agents, extreme-pressure additives, viscosity index improvers, pour point depressants, viscosity modifiers, or any combination thereof.

In one embodiment of the present invention disclosure, the weight percent of the antioxidant with respect to the total weight of the coolant composition may be 3.0% by weight or less such as more than 0% by weight to 3.0% by weight or less, 0.01% by weight to 2.5% by weight, 0.05% by weight to 2.0% by weight, 0.1% by weight to 1.0% by weight, or 0.5% by weight to 1.5% by weight. In an embodiment, the weight percent of the antioxidant may be 2.0% by weight or less such as more than 0% by weight to 2.0% by weight or less. In an embodiment, the weight percent of the antioxidant may be in a range of 0.05% by weight or more to 2% by weight or less.

In addition, the weight percent of the other additives with respect to the total weight of the coolant composition may be in a range of more than 0% by weight to 8% by weight such as 0.01% by weight to 7% by weight, 0.05% by weight to 6% by weight, 0.1% by weight to 5% by weight, 0.2% by weight to 3% by weight, 0.5% by weight to 2% by weight, or 1% by weight to 4% by weight. In an embodiment, the weight percent of the other additives may be in a range of more than 0% by weight to 5% by weight, more particularly may be in a range of 0.05% by weight to 5% by weight.

The coolant composition of the present invention disclosure may include a C value defined by the following formula in a predetermined range. The formula is defined as follows:

$$C = 0.17 \times \frac{{ρ}^{0.428} \times {C}_{p}^{0.397} \times {k}^{0.51}}{{μ}^{0.245}}$$

Herein, ρ represents density (g/cm³), Cₚ represents specific heat (J/g·° C.), k represents heat conductivity (W/mK), and μ represents kinematic viscosity (cSt). Individual parameters (density, specific heat, heat conductivity, and kinematic viscosity) of the formula are dependent on temperature. Accordingly, the parameters are measured at an identical specific temperature.

In one embodiment of the present invention disclosure, the coolant composition may have a C value in a range of 3.000×10⁻² to 4.950×10⁻² when measured at a temperature of 40° C. The specific numerical range is required to be understood as including an arbitrary sub-range between the lower and upper bounds. The C value range of 3.000×10⁻² to 4.950×10⁻² includes subranges such as 3.000×10⁻² to 3.200×10⁻², 3.200×10⁻² to 3.700×10⁻², 3.600×10⁻² to 4.200×10⁻², 4.100×10⁻² to 4.600×10⁻², and 4.500×10⁻² to 4.950×10⁻². Particularly, the C value range may be 3.200×10⁻² to 4.930×10⁻². More particularly, the C value range may be 3.250×10⁻² to 4.920×10⁻². Even more particularly, the C value range may be 3.600×10⁻² to 4.920×10⁻².

In the case of a composition having a C value falling outside of the described range above, the composition may not be used as a coolant composition For example, when the C value of the composition is less than 3.000×10⁻², the efficiency of a pump for moving the composition may decrease significantly, and/or the cooling performance of the composition itself may decline. Conversely, when the C value of the composition is more than 4.950×10⁻², the amount of light components of the composition that may be readily vaporized or the amount of the vaporized composition may increase significantly, and as the result the flash point of the composition may be reduced significantly so that there is a higher risk of fire.

In one embodiment of the present invention disclosure, the coolant composition may have an electro-conductivity from 0 pS/m or more to 20 pS/m or less as measured by IEC 60247. Particularly, the coolant composition may have an electro-conductivity of 19 pS/m or less, more particularly electro-conductivity of 18 pS/m or less, and even more particularly electro-conductivity of 16 pS/m or less, and even more particularly electro-conductivity of less than 15 pS/m.

In the case of the composition having an electro-conductivity of more than 20 pS/m, electricity may flow through the composition, and thus there is a risk of short-circuit within equipment or system so that the equipment or system may be damaged.

It has been rather unexpectedly found that the coolant composition of the present invention disclosure which fulfills at least one of the conditions such as the predetermined C value described above or electro-conductivity, and particularly both, exhibits that excellent performance in insulation and cooling are all possible to be achieved.

The present invention disclosure provides equipment containing the coolant composition according to the first aspect as well. In addition, the present invention disclosure provides a method of cooling equipment by using the coolant composition.

The type of the equipment is not particularly limited when the equipment requires the removal of heat generated in use. Particularly, the equipment may be electronic products, and in particular secondary type batteries of such electronic products and the electronic circuits of the electronic products. Examples may be electric vehicles, specifically a secondary battery system for electric vehicles; or heat generated by data servers; energy storage devices, and the like. However, these are just examples and the use of the inventive coolant composition may not be limited to these applications only.

The equipment may be cooled by being made to be in contact, or brought to be in contact with the coolant composition either directly or indirectly (e.g., the coolant being contained in container or pipe) of the present invention disclosure. Particularly, the equipment may be cooled by being made to be in or brought to be in a direct contact with the coolant composition. Due to high electro-conductivity of water, a refrigerant of water cooling, water cooling is difficult to make the “direct contact”, a method of cooling the equipment through a direct contact. In addition, air cooling uses air as a medium of heat exchange, which means it is possible to make a direct cooling, but cooling efficiency decreases due to a low specific heat capacity of air. The coolant composition of the present invention disclosure makes it possible to directly cool sources of heat generation, which ultimately makes it possible to achieve a significantly improved cooling efficiency compared to the ones obtained with existing conventional cooling methods.

Hereinafter, examples are proposed for better understanding of the present invention disclosure, however, the following examples are just provided to help better understanding of the present invention disclosure, and the present invention may not be limited to these examples only.

### EXAMPLES

### 1. Preparing Coolant Composition

Coolant compositions including a 97.5% by weight base oil, a 0.5% by weight antioxidant, and 2% by weight other additives are prepared in Preparation Examples 1 to 5, and Comparative Preparation Example 1. Properties of the base oil included in the individual coolant compositions are as provided in the following Table 1.

TABLE 1

| | | | | | | Comparative |
|---|---|---|---|---|---|---|
| | Preparation | Preparation | Preparation | Preparation | Preparation | Preparation |
| | Example 1 | Example 2 | Example 3 | Example 4 | Example 5 | Example 1 |
| Average number of | 31~35 | 26~30 | 19~23 | 17~21 | 15~19 | 43~47 |
| carbon atoms | | | | | | |
| 5 wt % distiliation | 390~410 | 370~390 | 280~300 | 280~300 | 245~265 | 445~465 |
| temperature (° C.) | | | | | | |
| 95 wt % distillation | 520~540 | 455~475 | 410~430 | 395~415 | 340~360 | 615~635 |
| temperature (° C.) | | | | | | |
| Paraffin volume | 55~65 | 60~70 | 45~55 | 70~80 | 45~55 | 80~90 |
| percent (vol %) | | | | | | |

Physical characteristics of the individual coolant compositions (At temperature 40° C.) are as provided in the following Table 2.

TABLE 2

| | | | | | | | Comparative |
|---|---|---|---|---|---|---|---|
| | Measuring | Preparation | Preparation | Preparation | Preparation | Preparation | Preparation |
| | method | Example 1 | Example 2 | Example 3 | Example 4 | Example 5 | Example 1 |
| Density | ASTM | 0.8259 | 0.8206 | 0.819 | 0.79965 | 0.7953 | 0.8198 |
| (g/cm³) | D4052 | | | | | | |
| Heat conductivity | ASTM | 0.1448 | 0.1388 | 0.1283 | 0.1317 | 0.1256 | 0.1555 |
| (W/mK) | D7896 | | | | | | |
| Specific heat | ASTM | 2.0839 | 2.0241 | 1.8962 | 1.9875 | 1.9172 | 2.2277 |
| (J/g ° C.) | D7896 | | | | | | |
| Kinematic | ASTM | 35.16 | 19.60 | 8.772 | 6.517 | 4.050 | 61.80 |
| viscosity (cSt) | D445 | | | | | | |
| Flash point | ASTM | 244 | 224 | 170 | 165 | 130 | 271 |
| (° C.) | D92 | | | | | | |
| Electro- | | <15 | <15 | <15 | <15 | <15 | <15 |
| conductivity | | | | | | | |
| (pS/m) | | | | | | | |
| C Value | | 0.03271 | 0.03641 | 0.04147 | 0.04559 | 0.04917 | 0.02982 |

### 2. Cooling Performance Test

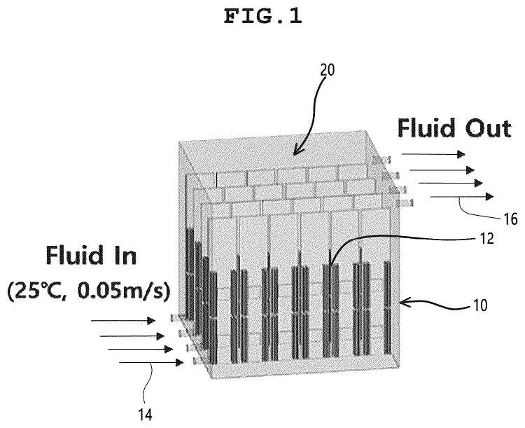

Cooling of the server of a data center was simulated by using the coolant compositions, as shown in Preparation Examples 1 to 5, and Comparative Preparation Example 1. The schematic view of the simulation is described in FIG. 1, and the configurations of the server of the data center are as provided in Table 3.

TABLE 3

| | Board | CPU | Memory | Bathtub |
|---|---|---|---|---|
| Number | 24 | 48 | 384 | — |
| Thickness, mm | 10 | 4 | 2 | 600 |
| Width, mm | 90 | 40 | 30 | 600 |
| Height, mm | 500 | 40 | 150 | 600 |
| Amount of heat | — | 12.5 | 1.56 | — |
| generation, W/ea | | | | |

Referring to FIG. 1, Inflow 14 and outflow 16 of the coolant compositions 20 into the bathtub 10 took place, and cooling was executed in a method of immersion cooling meaning that the data server circuits 12 in the bathtub 10 are immersed in the coolant 20 The inflow 14 of the coolant compositions took place at a temperature of 25° C., and at a speed of 0.05 m/s.

The simulation results by using the individual compositions are as provided in the following Table 4.

TABLE 4

| | | | | | | Comparative |
|---|---|---|---|---|---|---|
| | Preparation | Preparation | Preparation | Preparation | Preparation | Preparation |
| | Example 1 | Example 2 | Example 3 | Example 4 | Example 5 | Example 1 |
| CPU Average | 55.5 | 52.4 | 49.1 | 46.9 | 45.3 | 58.5 |
| temperature (° C.) | | | | | | |

As a result of the simulation, the temperature of CPU cooled by the coolant compositions, as shown in Preparation Examples 1 to 5, was maintained in a range of 45° C. to 56° C., and other limitations such as electrical current passing or short-circuit were not observed despite the execution of immersion cooling. Thus, the coolant composition of the present invention disclosure is expected to be used as a new coolant to cool electronic products in which high heat is generated. Meanwhile, in the case of Comparative Preparation Example 1 having a C value outside the above mentioned ranges present invention disclosure, had less efficient cooling performance compared with Preparation Examples 1 to 5. 1 to 2° C. or more difference in temperature in the simulation under the same conditions may be understood as very significant to the ordinarily skilled in the art, and the difference may be considered to be more outstanding in the application to large-scale electronic devices generating a lot more heat.

Simple modifications or alterations in the present invention disclosure are all included in the present invention disclosure, and the detailed protection scope is clarified based on the appended claims.

What is claimed is:

1. A coolant composition having a C value in a range of 3.000×10⁻² to 4.950×10⁻², the C value defined by the following formula:
$$C = 0.17 \times \frac{{ρ}^{0.428} \times {C}_{p}^{0.397} \times {k}^{0.51}}{{μ}^{0.245}}$$
wherein, ρ represents density (g/cm³), Cₚ represents specific heat (J/g·° C.), k represents heat conductivity (W/mK), and μ represents kinematic viscosity (cSt).

2. The coolant composition of claim 1, wherein the coolant composition comprises mineral base oil in an amount of at least 90% by weight with respect to the total weight of the coolant composition.

3. The coolant composition of claim 2, wherein the mineral base oil is characterized by at least one of the following parameters:
an average carbon number measured based on ASTM D2887 of 15 to 35 carbon atoms;
a 5% by weight distillation temperature measured based on ASTM D2887 in a range of 240° C. to 410° C.;
a 95% by weight distillation temperature measured based on ASTM D2887 in a range of 330° C. to 570° C.; and
a paraffin volume measured based on ASTM D2786 of 90% or less based on the total volume of the mineral base oil.

4. The coolant composition of claim 3, wherein the mineral base oil is characterized by at least two of the parameters listed in claim 3.

5. The coolant composition of claim 3, wherein the mineral base oil is characterized by at least three of the parameters listed in claim 3.

6. The coolant composition of claim 3, wherein the mineral base oil is characterized by all four of the parameters listed in claim 3.

7. The coolant composition of claim 1, wherein the coolant composition further comprises an additive.

8. The coolant composition of claim 7, wherein the additive comprises an antioxidant and other additives.

9. The coolant composition of claim 7, wherein the other additives comprise an antifoamer, a corrosion inhibitor, a detergent, a dispersing agent, a friction modifier, an anti-wear agent, an extreme-pressure additive, a viscosity index improver, a pour point depressant, a viscosity modifier, or any combination thereof.

10. The coolant composition of claim 1, wherein the coolant composition has an electro-conductivity from 0 pS/m or more to 20 pS/m or less as measured by IEC 60247.

11. Equipment comprising the coolant composition of claim 1, wherein the coolant composition is used for removing heat generated by the equipment, and wherein the equipment is directly cooled by the coolant composition.

12. A method of cooling an equipment, the method comprising:
providing the coolant composition of claim 1 in direct contact with the equipment, wherein the equipment in operation generates heat which is directly removed via the coolant composition.
